(19) United States
(12) Patent Application Publication
(10) Pub. No.: US 2004/0107393 A1
(43) Pub. Date: Jun. 3, 2004

(54) Method and device for testing the mapping/implementation of a model of a logic circuit onto/in a hardware emulator

(76) Inventors: Herbert Taucher, Moedling (AT); Karltheinz Krause, Planegg (DE); Majid Ghameshlu, Kopalgasse (AT)

Correspondence Address: SIEMENS SCHWEIZ, I-44, INTELLECTUAL PROPERTY, ALBISRIEDERSTRASSE 245, ZURICH, CH-8047, CH

(21) Appl. No.: 10/670,567

(22) Filed: Sep. 26, 2003

(30) Foreign Application Priority Data
Sep. 30, 2002 (EP) 02 021 974.7

(51) Int. Cl. G01R 31/28

(52) U.S. Cl. 714/724

(57) ABSTRACT

A method for testing an emulated logic circuit is described wherein a model of the logic circuit is loaded into a hardware emulator (EM) and there put into an operating mode in which flip-flops it contains are functionally chained into one or more shift registers. The structural arrangement of the logic circuit in the hardware emulator (EM) is subsequently compared with the structural arrangement of the model of the logic circuit with the assistance of this operating mode. A device for implementing the method is also described.

### BACKGROUND OF THE INVENTION

The invention relates to a method for testing an emulated logic circuit wherein a model of a logic circuit is loaded into a hardware emulator in a hardware description language. The invention further relates to a device for implementing the method according to the invention.

The complexity of modern logic circuits requires function tests to be performed at an early stage during the design phase itself in order to minimize the expense of any necessary corrections. For this reason, extensive possibilities exist for testing a logic circuit simulated in a programmable computer. The necessary functions are often already incorporated in the design software.

Despite the high level of computing power offered by modern computers, an at least broadly complete function test cannot be performed on an extensive logic circuit within a reasonable time on a purely simulation-supported basis. An example of such a circuit is what is called an “application-specific integrated circuit”, abbreviated to ASIC.

For this reason, use has long been made of hardware emulators which consist of a large number of parameterizable logic gates which can be flexibly inter-linked. The model of the logic circuit generated on the computer is loaded for the function test into the hardware emulator which simulates the logic circuit under test by means of suitable parameterizing. By providing appropriate connections at the emulator's inputs and outputs, usually done with the aid of a programmable computer, the test can be performed in a relatively short time because individual switching processes take place significantly faster in a hardware emulator than would be the case with software simulation. The model of the logic circuit is in the form of, for instance, what is called a “Register Transfer Level Model” or of a netlist.

The use of hardware emulators gives rise to further problems, however. On the one hand the model of a logic circuit stored in a programmable computer has to be mapped onto a netlist on the hardware emulator. Owing to its complexity, this process takes place on a computer-supported basis and is difficult for a people to follow, for which reason any faults that occur are virtually undetectable.

Another source of faults is to be found in failed modules in the hardware emulator not yet recognized as having failed. Even if the process of mapping the model of the logic circuit onto the netlist is error-free, a defective module whose function is to emulate part of the logic circuit will generally result in malfunctioning of the emulated logic circuit.

It is unfortunately not possible at present to distinguish whether a malfunction in the logic circuit is due a design fault, to a fault during the process of mapping onto the netlist, or to a defect in the hardware emulator because possibilities of conducting a self-test on a hardware emulator either do not exist or are only minor in scope. Fault analysis is accordingly time-consuming and also error-prone itself.

### BRIEF SUMMARY OF THE INVENTION

The object of the invention is therefore to specify a method for testing the mapping/implementation of a model of a logic circuit onto/in a hardware emulator which does not exhibit the cited disadvantages.

This object is achieved according to the invention by means of a method of the type mentioned at the start

wherein the emulated logic circuit is put into an operating mode in which some or all of the flip-flops it contains, in particular with additional logic elements as interfacing circuitry, are functionally chained into one or more shift registers, and

wherein the structural arrangement of the logic circuit in the hardware emulator is compared with the structural arrangement of the model of the logic circuit at least partially with the assistance of this operating mode.

The functioning of the logic circuit under test is particularly simple and therefore easy to follow thanks to the chaining of the individual flip-flops into one or more shift registers. With the assistance of this operating mode of the logic circuit, which is also known by the term “scan mode”, with relatively little technical effort it is possible to make an initial statement about whether the structural arrangement of the logic circuit in the hardware emulator is comparable or identical at all to the structural arrangement of the modeled logic circuit.

Only if parity exists can correct mapping of the model of the logic circuit onto the hardware emulator and correct functioning of the hardware emulator be assumed. These are essential preconditions for starting a meaningful test of the design of the logic circuit; it would otherwise, as a general rule, be uncertain whether unexpected behavior on the part of the circuit was due to a design fault or a fault in mapping onto the hardware emulator.

Since the scan mode necessary for the method according to the invention often in any event forms a constituent part of the model of the logic circuit, it is very easy to implement the invention there.

As a supplementary comment, the scan mode mentioned here differs in its purpose from the IEEE 1149.1 standard specified by the Joint Test Action Group, abbreviated to JTAG, which substantially relates to function testing in connection with printed circuits.

Although flip-flops are also chained into shift registers there, the purpose of this is not to test the flip-flops per se or their interconnections but rather to allow testing of components on a printed circuit with the aid of a standardized interface without the components under test mandatorily requiring a direct connection to this interface but generally only being accessible via other components which are set to a special scan mode.

It is also particularly advantageous

if a test pattern is applied to the emulator inputs, which simultaneously represent inputs of shift registers, and is shifted into the shift registers by means of suitable pulsing,

if the emulated logic circuit is set to a standard operating mode, one or more pulsing cycles ensue, and the circuit then re-set to the original operating mode,

if the ensuing result pattern is shifted by means of suitable pulsing to emulator outputs which simultaneously represent outputs of the shift registers, and a check is carried out there to determine whether the pattern matches an expected value, and

if this result is used to compare the structural arrangement of the logic circuit in the hardware emulator with the structural arrangement of the model of the logic circuit.

In this embodiment of the invention, a test pattern which is preferably as many bits wide as there are inputs is applied to the inputs of the emulator or of the shift registers and shifted into the shift register. Although this shifting can basically take place any number of times, it is advantageous to fill all flip-flops with a known value by shifting the pattern up to the end position, which is to say up to the outputs of the shift registers. After this shifting, the logic circuit is set to a standard operating mode in which it performs the functions for which it was actually designed. This is preferably followed by one pulsing cycle or also several pulsing cycles, as a result of which the flip-flops are set to a condition corresponding to their logical linking. The logic circuit is then re-set to the “scan mode” and the result pattern shifted by means of suitable pulsing to the outputs of the hardware emulator. It is compared there with an expected value which is known from, for instance, the model of the logic circuit. If the result pattern does not match the expected value, it may be assumed that the logic circuit was not correctly mapped onto the hardware emulator or that the hardware emulator is defective.

It is also advantageous

if a test pattern is applied to an emulator input which simultaneously represents the input of a shift register,

if the test pattern is shifted through the shift register by means of suitable pulsing,

if an emulator output which simultaneously represents the output of this shift register is checked for the appearance of this or of the inverted test pattern,

if the number of flip-flops in the shift register is determined from the number of pulsing sequences required for shifting through, and

if this result is used to compare the structural arrangement of the logic circuit in the hardware emulator with the structural arrangement of the model of the logic circuit.

Thanks to better comprehensibility a simple functional flow is presented, namely the application of a single bit to an input as a test pattern, preferably with all flip-flops previously being initialized with the value zero. This bit is subsequently further shifted through the shift register by means of suitable pulsing until it is detected at the output. If the pulse is coupled with a counting device, the number of flip-flops can be determined directly from the number of pulsing cycles required for shifting through. If the determined number of flip-flops does not match the number which is known from, for instance, the model of the logic circuit, it may be assumed that the model of the logic circuit was not correctly mapped onto the hardware emulator or that the hardware emulator is defective.

The case mentioned relates to a chaining of flip-flops containing no or an even number of inverted logic elements. The cited logical values must otherwise be reversed.

The method according to the invention can of course also be applied using another test pattern. Initializing of the flip-flops can, where applicable, be omitted if a suitable test is carried out for the appearance of the test pattern at the output of the shift register.

An advantageous embodiment of the invention is also provided with a method where the output of a shift register is connected to the input of a next adjacent shift register and all shift registers are chained into a single shift register by means of recursion. The function test is particularly simple in this case because only one bit has to be shifted through the shift register in order to determine the number of flip-flops in the shift register—provided all the flip-flops are initialized with the value zero. The number of flip-flops is determined directly by counting off the pulse edges required for this. If initializing of this kind is not possible, another test pattern can nonetheless be used for the function test in which case a suitable test for the appearance of the test pattern must be provided at the output of the shift register.

It is also favorable

if, in the event that the structural arrangement of the logic circuit in the hardware emulator does not match the structural arrangement of the model, an analysis is carried out to determine the sources of such faults, and

if the model of the logic circuit is automatically re-loaded into the hardware emulator with these sources of faults deactivated.

Since a check on whether a logic circuit's design actually does what is expected of it can generally only be performed to practical effect if the correctness of the mapping of the model of the logic circuit onto the hardware emulator is ensured, the model is automatically re-loaded into the hardware emulator if this condition does not apply. This allows the flow of the function test to be devised in a particularly advantageous manner, with the faults leading to the lack of matching being analyzed and avoided during the ensuing loading process by means of suitable parameterizing of the loading process. A fault of this kind can be due, for instance, to a defective module in the hardware emulator. This process will, if necessary, have to be iterated if further faults occur on re-loading.

The object of the invention is also achieved by means of a device for implementing all the steps of a method

which comprises a hardware emulator for emulating a logic circuit present in the form of a model, a test pattern generator module for applying a test pattern to an input of the hardware emulator, a pulse generator for injecting a pulse into the hardware emulator, and a test pattern checking module for checking whether a bit pattern being applied to an output of the hardware emulator matches an expected value, and

which additionally contains a module for comparing the structural arrangement of the logic circuit in the hardware emulator with the structural arrangement of the model of the logic circuit at least partially with the assistance of an operating mode of the logic circuit in which some or all of the flip-flops it contains, in particular with additional logic elements as interfacing circuitry, are functionally chained into one or more shift registers.

The device according to the invention provides the essential requirements for facilitating function testing of the logic circuit with the assistance of a scan mode and for allowing a statement to be made about whether the structural arrangement of the logic circuit in the hardware emulator is comparable or identical at all to the structural arrangement of the logic circuit in the model of the logic circuit.

It is particularly advantageous here if the device includes a module for determining the number of flip-flops in the shift register from the number of pulse sequences needed to shift a test pattern through the register and/or a module for briefly changing over the logic circuit to a standard operating mode for one pulse cycle or several pulse cycles while a test pattern is being shifted through the register.

With the aid of the device it is possible, for instance, to determine the number of flip-flops in the logic circuit in a simple manner and thus to evaluate a condition for the parity of the model of the logic circuit and its mapping in the hardware emulator. The possibility of changing over to a standard operating mode means that the test possibilities provided by the device are, as an additional feature, extended.

An advantageous embodiment of the invention is also provided with a device which includes a module for chaining all the shift registers into a single shift register by means of recursively connecting the output of, in each case, one shift register to the input of, in each case, one next adjacent shift register.

As mentioned earlier in connection with the method according to the invention, the function test is particularly simple in this case owing to the presence of a single shift register. The device according to the invention also ensures this possibility of testing in the case of logic circuits which do not have an internal chaining possibility of this kind.

It is also favorable

if this includes a module for analyzing the sources of faults leading to a lack of matching between the structural arrangement of the logic circuit in the hardware emulator and the structural arrangement of the model, and

if this includes a module for automatically loading the model of the logic circuit into the hardware emulator with these sources of faults deactivated.

This embodiment of the invention provides an advantageous device for conveniently performing a function test on a model of a logic circuit because, with the aid of the module for automatic loading, the model will be re-loaded into the hardware emulator if the correctness of the mapping of the model onto the hardware emulator is not ensured. The faults leading to this lack of matching are analyzed with the aid of a suitable module and are avoided during the ensuing loading process by means of suitable parameterizing of the loading process. A fault of this kind can be due, for instance, to a defective module in the hardware emulator.

Attention is incidentally drawn to the fact that the cited advantages of the method according to the invention apply equally to the relevant device according to the invention, and vice versa.

### BRIEF DESCRIPTION OF THE SEVERAL VIEWS OF THE DRAWINGS

The invention will now be explained in further detail with the aid of an exemplary embodiment shown in the figures which relates to the performance of a function test on a logic circuit mapped in a hardware emulator.

FIG. 1: shows a test arrangement for implementing the method according to the invention by means of chaining the individual flip-flops and temporarily changing over the logic circuit to a standard operating mode;

FIG. 2: shows a test arrangement for applying the method according to the invention by means of chaining the individual flip-flops into a single shift register.

### DETAILED DESCRIPTION OF THE INVENTION

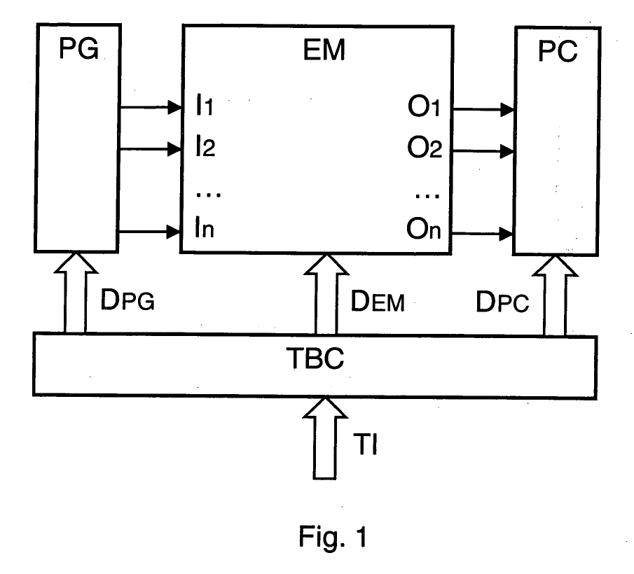

FIG. 1 comprises a hardware emulator EM, a test pattern generator PG, a test pattern checking module PC, and a test control module TBC. The test pattern generator PG is connected via n connections to a first to nth input I1 . . . In of the hardware emulator EM. Analogously to this, the test pattern checking module PC is connected via n connections to a first to nth output O1 . . . On of the hardware emulator EM. Proceeding from the test controller TBC, the device further comprises a data link to the test pattern generator DPG, a data link to the test pattern checking module DPC, and a data link to the hardware emulator DEM. Finally, there is also a data link to the test controller TI.

The function of the device shown in FIG. 1 is as follows:

The information needed for the test, such as the test patterns on which the test is based, is transmitted over the data link to the test controller TI. The logic circuit mapped in the hardware emulator is then put into an operating mode in which preferably all the flip-flops it contains, or also other logic elements such as inverters, are functionally chained into several shift registers.

From the test controller TBC, the test pattern generator PG then receives the instruction to apply a specific test pattern to the first to nth input I1 . . . In of the hardware emulator EM. In like manner, the result patterns expected on the first to nth output O1 . . . On of the hardware emulator EM are transmitted to the test checking module PC by the test controller TBC.

The actual test is finally started by the application of a pulse to the hardware emulator EM by the pulse controller TBC. In this way, specific, varying test patterns which are applied by the test pattern generator PG to the first to nth input I1. In of the hardware emulator EM are successively switched through the emulated logic circuit by the flip-flops which have been connected into a shift register, preferably until all the shift registers have been initialized with a defined value.

The logic circuit is then put into a standard operating mode in which the individual flip-flops and other components are logically linked with each other in keeping with the logic circuit's functional purpose. The flip-flops are therefore not mandatorily organized as a shift register. One pulse edge is then applied to the circuit, although several are also possible. However, owing to the logic circuit's mode of operating in this condition, the test pattern is now not merely shifted further; what happens instead is that the flip-flops are occupied totally afresh depending on their mutual logical linking. This result pattern which is also known from, for instance, the simulation of the model of the logic circuit is then shifted to the first to nth output O1 . . . On through repeated changing over of the logic circuit into the scan mode and appropriate pulsing.

It is now possible to determine with the aid of the test pattern checking module PC whether the result value being applied to the first to nth output O1 . . . On matches the expected result value.

If the expected result patterns are identical to the result patterns actually being applied to outputs Ox, it may be assumed that, on the one hand, the hardware emulator EM is working properly and furthermore that, on the other hand, the model of the logic circuit under test was also correctly mapped onto the netlist of the hardware emulator EM.

It is mentioned here as a supplementary comment that account must be taken during the function test of the chaining of the shift registers with inverters and of the different lengths of the individual shift registers. Depending on the number of inverters contained, the former results in possibly inverted bit patterns; the latter results in a bit pattern applied to inputs Ix at a specific time being visible at outputs Ox at different times.

Further use can also be made of the bit patterns needed for the function test for hardware testing of the resulting silicon chip containing the logic circuit, which is why the production chain, from design right through to actual fabrication and final testing, is especially efficient in that it requires minimum effort.

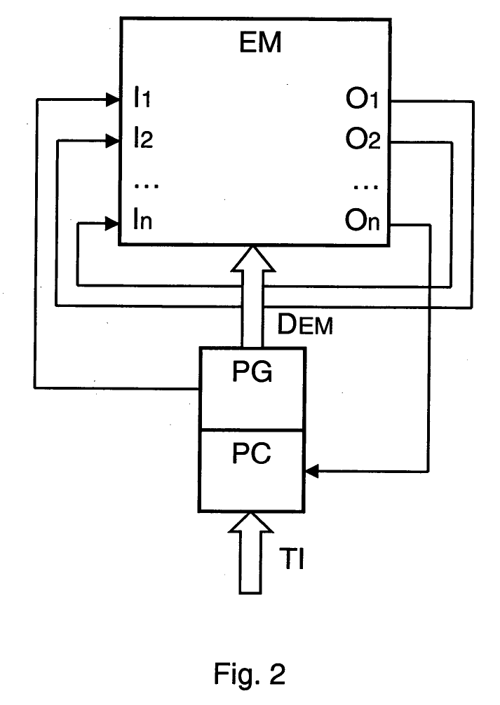

FIG. 2 shows a simplified device for implementing the method according to the invention. This again comprises a hardware emulator EM, a test pattern generator PG, and a test pattern checking module PC. In contrast to what is shown in FIG. 1, however, the first output O1 of the hardware emulator EM is connected to the second input I2, the second output O2 is connected to the third input I3 etc., so that only the nth output On is not connected to an input Ix of the hardware emulator EM.

The test pattern generator PG is finally connected to the first input I1, and the nth output On is connected to the test pattern checking module PC. The device also includes a data link to the hardware emulator DEM and a data link to the test pattern checking module TI.

The function of the device shown in FIG. 2 is as follows:

Because the individual shift registers are chained into a single shift register by means of the circuitry shown it is easier to switch through a test pattern, which can now be shifted through the shift register bit by bit. At the nth output On, account only needs to be taken of the number of inverters the shift registers may contain. If it is an odd number, the test pattern appears inverted at the nth output On. It is not necessary to take account of different register lengths as is required in the case of the arrangement shown in FIG. 1.

If the test pattern injected into the first input I1 can then be ascertained at the nth output On, a conclusion can be drawn about the number of flip-flops the register contains by evaluating the pulse cycles required for passing the test pattern through. If the ascertained number does not match the number known from the model of the logic circuit, a fault may be assumed to have occurred.

A simple test pattern is, for example, a single bit which is shifted through the shift register, with the associated need to ensure that the individual flip-flops have been initialized with the value zero.

What is claimed is:

1. Method for function testing an emulated logic circuit wherein a model of a logic circuit is loaded into a hardware emulator (EM) in a hardware description language, wherein:
the emulated logic circuit is put into an operating mode in which some or all of the flip-flops it contains, in particular with additional logic elements as interfacing circuitry, are functionally chained into one or more shift registers, and
the structural arrangement of the logic circuit in the hardware emulator (EM) is compared with the structural arrangement of the model of the logic circuit at least partially with the assistance of this operating mode.

2. Method according to claim 1, wherein:
a test pattern is applied to inputs (Ix) of the emulator (EM), which simultaneously represent inputs of shift registers, and is shifted into the shift registers by means of suitable pulsing,
the emulated logic circuit is set to a standard operating mode, one or more pulsing cycles ensue, and the circuit then re-set to the original operating mode,
the ensuing result pattern is shifted by means of suitable pulsing to emulator (EM) outputs (Ox) which simultaneously represent outputs of the shift registers, and a check is carried out there to determine whether the pattern matches an expected value, and
this result is used to compare the structural arrangement of the logic circuit in the hardware emulator (EM) with the structural arrangement of the model of the logic circuit.

3. Method according to claim 1, wherein:
a test pattern is applied to an emulator (EM) input (Ix) which simultaneously represents the input of a shift register,
the test pattern is shifted through the shift register by means of suitable pulsing,
an emulator (EM) output (Ox) which simultaneously represents the output of this shift register is checked for the appearance of this or of the inverted test pattern,
the number of flip-flops in the shift register is determined from the number of pulsing sequences required for shifting through, and
this result is used to compare the structural arrangement of the logic circuit in the hardware emulator (EM) with the structural arrangement of the model of the logic circuit.

4. Method according to claim 3, wherein the output of a shift register (Ox) is connected to the input of a next adjacent shift register (Ix+1) and all shift registers are chained into a single shift register by means of recursion.

5. Method according to one of claim 1, wherein
in the event that the structural arrangement of the logic circuit in the hardware emulator (EM) does not match the structural arrangement of the model, an analysis is carried out to determine the sources of such faults, and
the model of the logic circuit is automatically re-loaded into the hardware emulator (EM) with these sources of faults deactivated.

6. A Device for testing an emulated logic circuit, comprising: a hardware emulator (EM) for emulating a logic circuit present in the form of a model, a test pattern generator module (PC) for applying a test pattern to an input (Ix) of the hardware emulator (EM), a pulse generator for injecting a pulse into the hardware emulator (EM), and a test pattern checking module (PC) for checking whether a bit pattern being applied to an output (Ox) of the hardware emulator (EM) matches an expected value, the device additionally contains a module for comparing the structural arrangement of the logic circuit in the hardware emulator (EM) with the structural arrangement of the model of the logic circuit at least partially with the assistance of an operating mode of the logic circuit in which some or all of the flip-flops it contains, in particular with additional logic elements as interfacing circuitry, are functionally chained into one or more shift registers.

7. The device according to claim 6, further comprising a module for determining the number of flip-flops in the shift register from the number of pulse sequences needed to shift a test pattern through the register and/or a module for briefly changing over the logic circuit to a standard operating mode for one pulse cycle or several pulse cycles while a test pattern is being shifted through the register.

8. The device according to claim 6, further comprising a module for chaining all the shift register into a single shift register by means of recursively connecting the output (Ox) of, in each case, one shift register to the input (Ix+1) of, in each case, one next adjacent shift register.

9. The device according to claim 6 further comprising
a module for analyzing the sources of faults leading to a lack of matching between the structural arrangement of the logic circuit in the hardware emulator (EM) and the structural arrangement of the model, and
a module for automatically loading the model of the logic circuit into the hardware emulator (EM) with these sources of faults deactivated.
